(19) United States
(12) Patent Application Publication
(10) Pub. No.: US 2009/0320917 A1
(43) Pub. Date: Dec. 31, 2009

(54) SOLAR CELL PASSIVATION AND LEVELING

(76) Inventors: Hing Wah Chan, San Jose, CA (US); Michael Ludowise, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 12/164,176

(22) Filed: Jun. 30, 2008

(51) Int. Cl. H01L 31/00; H01L 21/00

(52) U.S. Cl. 136/256; 438/72

(57) ABSTRACT

A device and a system to fabricate a device including a semiconductor mesa extending from a semiconductor base, the semiconductor mesa comprising an optically-active semiconductor area and a top surface, conductive material disposed on the top surface of the mesa, and substantially optically-transparent material disposed on the conductive material and on the top surface, wherein a surface of the substantially optically-transparent material above the conductive material and the top surface is substantially planar. In some aspects, the semiconductor mesa includes a side wall with one or more exposed p-n junctions, and material is disposed on the side wall to cover the one or more exposed p-n junctions.

### BACKGROUND

1. Field

Some embodiments generally relate to the conversion of solar radiation to electrical energy. More specifically, embodiments may relate to improved photovoltaic cells for use in conjunction with solar collectors.

2. Brief Description

A photovoltaic (or, “solar”) cell generates charge carriers (i.e., holes and electrons) in response to received photons. Many types of solar cells are known, which may differ from one another in terms of constituent materials, structure and/or fabrication methods. A solar cell may be selected for a particular application based on its efficiency, electrical characteristics, physical characteristics and/or cost.

Concentrating solar radiation collectors have been employed to increase the output of a solar cell for a given amount of semiconductor material. Generally, a concentrating solar radiation collector receives solar radiation (i.e., sunlight) over a first surface area and directs the received sunlight to an active area of a solar cell. The active area of the solar cell is several times smaller than the first surface area, yet receives substantially all of the photons received by first surface area. The solar cell may thereby provide an electrical output equivalent to a solar cell having the size of the first surface area.

FIG. 1A is a perspective view and FIG. 1B is a top view of a conventional solar cell that may reside within a concentrating solar collector. Solar cell 100 includes semiconductor base 110 and semiconductor mesa 120. Semiconductor mesa 120 may include one or more optically-responsive p-n junctions. Each junction may cause generation of charge carriers in response to different photon wavelengths. Mesa 120 is covered with conductor 130 for collecting current generated by solar cell 100 in response to received photons. Conductor 130 is disposed over the optically-active area of solar cell 100 in a grid-like pattern which facilitates suitable collection of the generated current.

A hermetic solar cell package is prohibitively expensive for solar power installations. Therefore, the optically-active area, conductor 130 and the edges of the aforementioned p-n junction(s) may be exposed to environmental hazards during operation. The optically-active area, conductor 130 and the edges of the aforementioned p-n junction(s) are also fragile and easily damaged by handling and packaging operations. These vulnerabilities may result in degraded cell performance and lifetime.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1A is a perspective view and FIG. 1B is a top view of a solar cell.

FIG. 2 is a perspective cutaway view of a portion of a solar cell according to some embodiments.

FIG. 3 is a flow diagram of a process according to some embodiments.

FIG. 4 is a perspective cutaway view of a portion of a solar cell according to some embodiments.

FIG. 5 is a perspective cutaway view of a portion of a solar cell according to some embodiments

FIG. 6 is a perspective cutaway view of a portion of a solar cell according to some embodiments

FIG. 7 is a cross-sectional view of a solar cell package according to some embodiments.

FIG. 8 is a cross-sectional view of a solar cell package according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

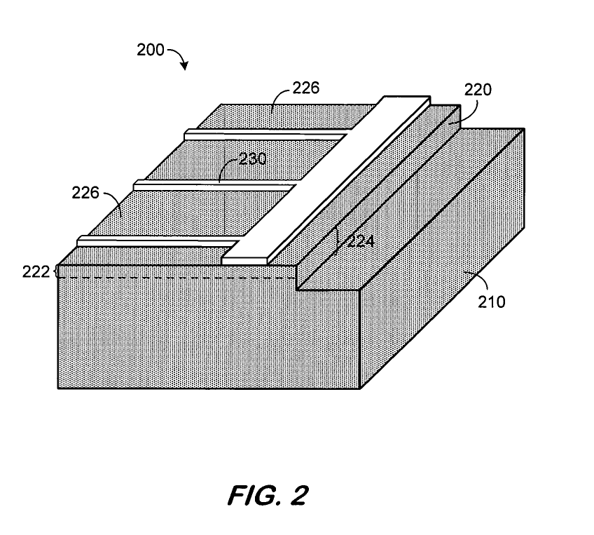

FIG. 2 is a perspective cutaway view of a portion of solar cell 200 according to some embodiments. Solar cell 200 may represent an instantiation of solar cell 100 described above, but embodiments are not limited thereto. As will be evident from the description below, embodiments are also not limited to the arrangement of FIG. 2.

Solar cell 200 may comprise a III-V solar cell, a II-VI solar cell, a silicon solar cell, or any other type of solar cell that is or becomes known. Solar cell 200 may comprise any number of active, dielectric and metallization layers, and may be fabricated using any suitable methods that are or become known.

Solar cell 200 comprises semiconductor base 210 and semiconductor mesa 220. Semiconductor mesa 220 and all other semiconductor mesas discussed herein may include one or more p-n junctions 222 deposited using any suitable method. Side wall 224 of mesa 220 includes exposed edges of p-n junctions 222. According to some embodiments, the junctions are formed using molecular beam epitaxy and/or metal organic chemical vapor deposition. The junctions may include a Ge junction, a GaAs junction, and a GaInP junction. Each junction exhibits a different band gap energy, which causes each junction to absorb photons of a particular range of energies and generate charge carriers in response thereto.

Conductive material 230 is disposed over an optically-active area of top surface 226 of mesa 220. Conductive material 230 may comprise a metal or any suitable conductor. Material 230 is disposed in a grid-like pattern over surface 226 to allow suitable collection of the current generated by solar cell 200.

Unshown portions of solar cell 200 may include contact material to facilitate electrical connections between conductive material 230 and external circuitry. Contact material disposed on top surface 226 may exhibit a same polarity as conductive material 230, and contact material having an opposite polarity may be disposed on a bottom surface of solar cell 200. By virtue of the foregoing arrangement, current may flow between the “top side” and “bottom side” contact material while solar cell 200 generates charge carriers.

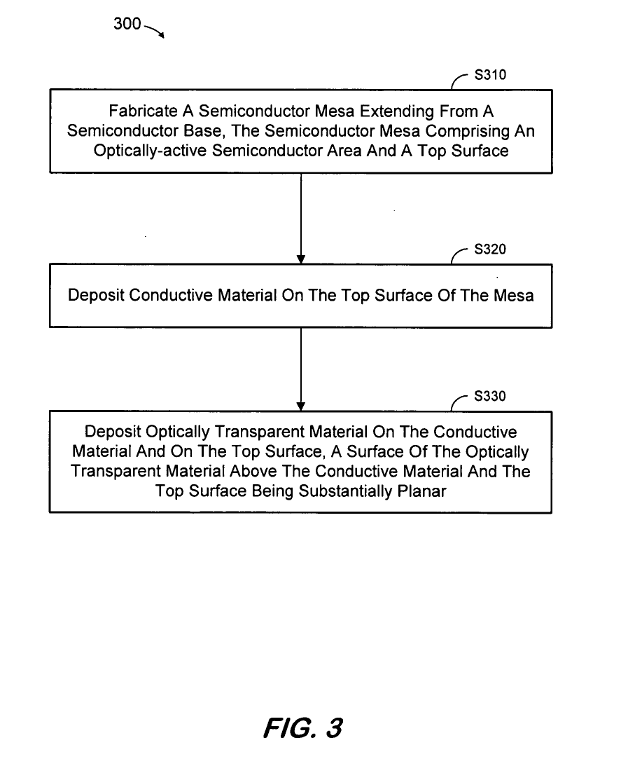

Process 300 of FIG. 3 may be executed to fabricate a device according to some embodiments. Process 300 may be executed using one or more fabrication devices, and all or a part of process 300 may be executed manually.

A semiconductor mesa extending from a semiconductor base is fabricated at S310. The semiconductor mesa comprises an optically-active semiconductor area and a top surface. For example, semiconductor mesa 220 including optically-active p-n junctions 222 and top surface 226 may be fabricated in some embodiments of S310. Embodiments are not limited to semiconductor mesas or p-n junctions described herein.

In some embodiments, many mesas such as semiconductor mesa 220 are formed on a single semiconductor wafer at S310. For example, p-n junctions may be fabricated on specific areas of the semiconductor wafer, and semiconductor material between each area may be removed via etching or partial depth cutting to result in an array of mesas on the wafer.

Conductive material is deposited on the top surface of the fabricated mesa at S320. Any suitable conductive material composition, pattern, thickness, etc. may be employed at S320. Returning to the above example, conductive material may be deposited at S320 on surface 226 in a pattern such as that formed by conductive material 230. In the case of an array of mesas formed on a single semiconductor wafer, conductive material may be deposited on each optically-active area prior to removal of semiconductor material between each area.

Some embodiments may employ a “flip-chip” solar cell, in which conductive material of opposite polarities is deposited on the top surface of the fabricated mesa at S320.

Next, at S330, a substantially optically-transparent material is deposited on the conductive material and on the top surface. A surface of the substantially optically-transparent material above the conductive material and the top surface is substantially planar. Examples of substantially optically-transparent material include, but are not limited to, SiN(H), SiO₂, Al₂O₃, polyamide, and spin-on glass. The substantially optically-transparent material may comprise any material(s) providing a desired combination of properties such as but not limited to those described below.

The substantially optically-transparent material deposited at S330 may comprise a single material or a combination of materials. The term “substantially optically-transparent” merely indicates that the material(s) may be substantially transparent to at least a portion of the visible and infrared spectrum with respect to which solar cell 200 is optically active.

The material deposited at S330 may exhibit a viscosity that results in the aforementioned substantially planar surface as well as conformance to the previously-deposited conductive material. Conformity to the conductive material may retard penetration of air of moisture into the conductive material, the top surface of the semiconductor mesa, and/or any other material deposited on the top surface. In this regard, an anti-reflective coating may be deposited on the top surface prior to S320 and/or on the conductive material and the top surface prior to S330.

The substantially optically-transparent material may comprise an anti-reflective coating. According to some embodiments, the substantially optically-transparent material also or alternatively exhibits a refractive index that is substantially similar to a refractive index of an optical gel that will be disposed thereon during packaging. Examples of such packaging will be described below.

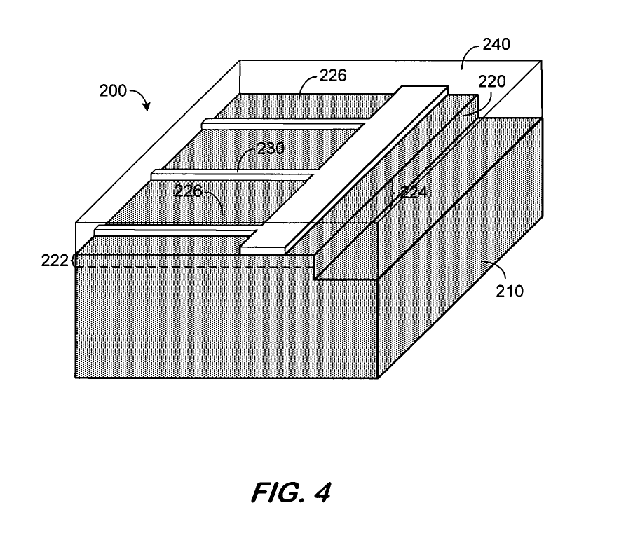

FIG. 4 illustrates solar cell 200 after some embodiments of S330. Substantially optically-transparent material 240 covers conductive material 230 and top surface 226 of semiconductor mesa 220. Deposition of material 240 at S330 has also resulted in material 240 covering exposed p-n junctions of side wall 224, but embodiments are not limited thereto.

Although only a portion of solar cell 200 is illustrated in FIG. 4, some embodiments of S330 comprise deposition of material 240 entirely over mesa 220 and continuously around a perimeter of mesa 220 so as to cover p-n junctions exposed around the perimeter. For example, in a case that process 300 is performed at the wafer level, optically-transparent material 240 may be deposited at S330 to cover the entire wafer. The resulting wafer may then be singulated into individual cells as represented in FIG. 4.

A solar cell according to process 300 may be integrated into a molded package. In some embodiments, such as those described in commonly-assigned U.S. patent application Ser. No. 12/046,152, filed Mar. 11, 2008 and entitled “Leadframe Receiver Package for Solar Concentrator”, the solar cell is electrically coupled to a leadframe and placed in a mold form having an opening to expose the optically-active area of the solar cell. The substantially planar surface of the substantially optically-transparent material may create a seal with the mold form around the opening. Accordingly, when molding compound is injected into the mold form, the seal may resist leakage of the molding compound onto a region above the optically-active area of the solar cell.

The substantially planar surface may also facilitate optical coupling of the optically-active area with the aforementioned optical gel. For example, in the absence of the substantially optically-transparent material (e.g., material 240), the optical gel would be placed directly on the top surface of the solar cell. However, the raised features of the conductive material (e.g., conductive material 230) also disposed on the top surface may cause air gaps between the optical gel and the top surface. These air gaps may degrade the optical coupling between the optical gel and the top surface.

Some embodiments may couple the substantially optically-transparent material directly to an optical element such as an optical rod. The substantially optically-transparent material may protect the fragile conductive material from pressure exerted by such an optical element. The substantially optically-transparent material may also provide a substantially index-matched optical path from the optical element to the optically-active area of the solar cell.

Coverage of exposed p-n junctions of the semiconductor mesa may also provide benefits in some embodiments. Suitable covering of the p-n junctions may prevent shorting of the p-n junctions and retard the buildup of leakage current over time. Moreover, the p-n junctions may be covered with a material (e.g., substantially optically-transparent material 240) the resists the penetration of moisture. According to some embodiments, the exposed p-n junctions may be covered by material deposited before the deposition of the substantially optically-transparent material at S330.

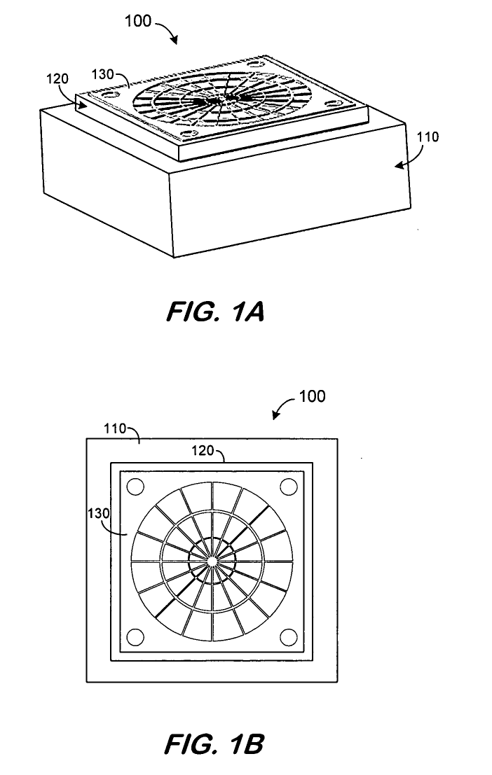

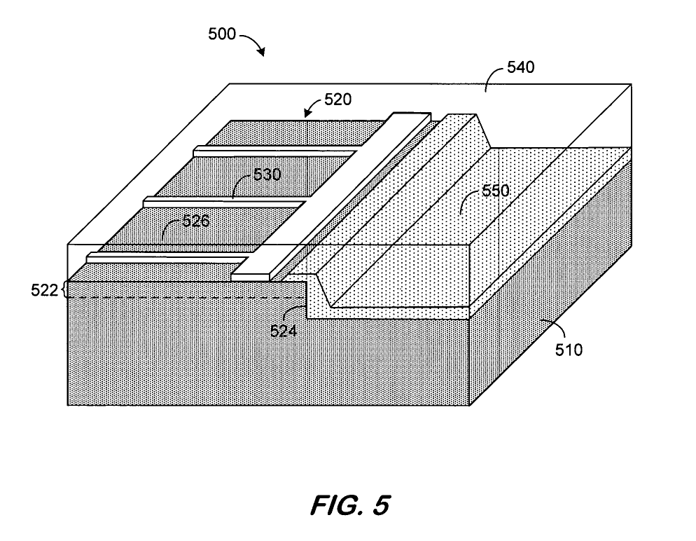

FIG. 5 is a perspective cutaway view of a portion of solar cell 500 according to some embodiments. Implementations of the elements of FIG. 5 may be similar to those described above with respect to similarly-numbered elements of FIGS. 1A, 1B and 4. As mentioned above, the exposed p-n junctions of side wall 524 are covered by material deposited before the deposition of the substantially optically-transparent material 540 at S330.

Material 550, which may comprise a dielectric, is disposed on semiconductor base 510, on side wall 524 of semiconductor mesa 520, and on top surface 526 of mesa 520. Material 350 may comprise SiN(H), SiO₂, Al₂O₃, and spin-on glass. According to some embodiments of process 300, material 550 comprises a SiN dielectric conformal coating applied after S330 in an annulus, a portion of which is depicted in FIG. 5. An anti-reflective coating is then deposited over top surface 526 and conductive material 530, followed by deposition of spin-on glass at S330. In some embodiments, material 550 is deposited as shown prior to deposition of conductive material 530 at S320.

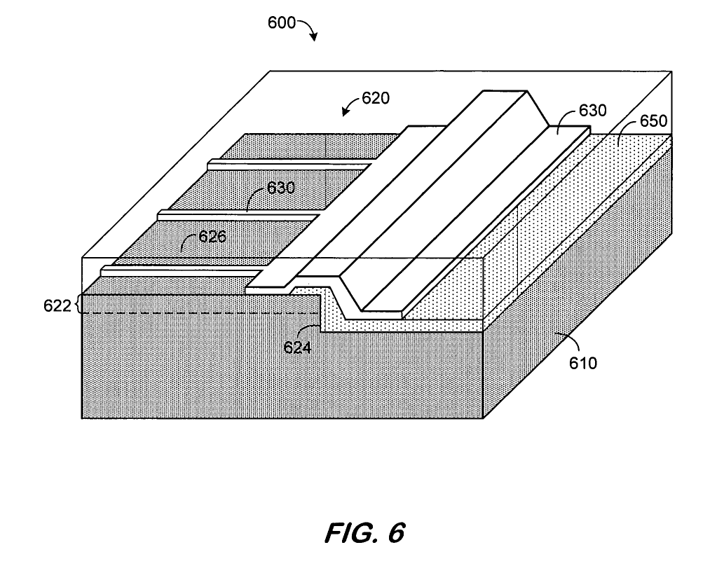

FIG. 6 is a perspective cutaway view of a portion of solar cell 600 according to some embodiments. Again, exposed p-n junctions of a semiconductor mesa are covered by material deposited before the deposition of substantially optically-transparent material at S330. Implementations of the elements of FIG. 6 may be similar to those described above with respect to similarly-numbered elements of FIGS. 1A, 1B, 4 and 5. Material 650 is disposed on semiconductor base 610, on side wall 624 of semiconductor mesa 620, and on top surface 626 of mesa 620.

Solar cell 600 comprises an implementation of a solar cell described in commonly-assigned U.S. patent application Ser. No. 12/050,516, filed Mar. 18, 2008 and entitled “Improved Solar Cell”. Moving from the left to the right of FIG. 6, conductive material 630 is disposed directly on top surface 626 of semiconductor mesa 620, overlaps material 650 on top surface 626, overlaps material 650 on side wall 624, and overlaps material 650 on a portion of base 610. Due to the foregoing arrangement, material 650 is deposited prior to deposition of conductive material 630 at S320. Material 650 and conductive material 630 are continuous around a perimeter of semiconductor mesa 620 in some embodiments.

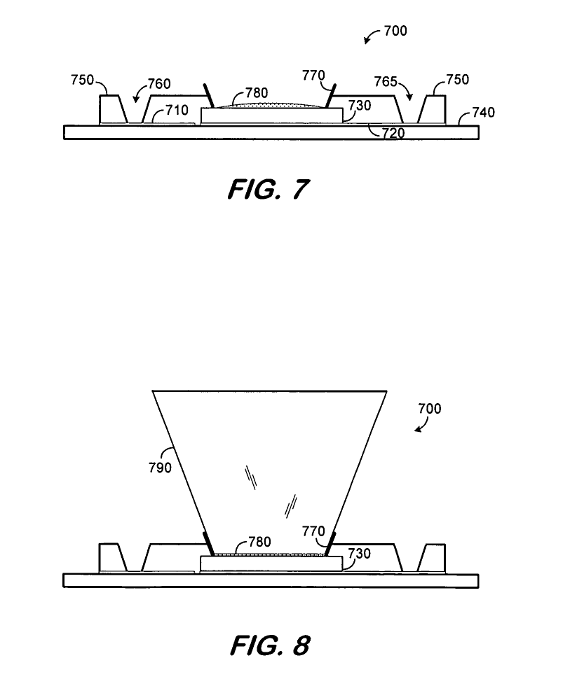

FIGS. 7 is a cutaway view of a molded package as mentioned herein and described in aforementioned U.S. patent application Ser. No. 12/046,152. Package 700 includes conductive leadframe elements 710 and 720 which are electrically coupled to respective conductive elements of solar cell 730. Solar cell 730 may be configured and/or fabricated in accordance with any solar cell described herein.

Conductive elements 710 and 720 and coupled to insulating substrate 740, which may or may not comprise mold compound. Substrate 740 may in turn be coupled to a heat spreader in some embodiments. Mold compound 750 may define apertures 760 and 765 for electrical connection to conductive elements 710 and 720.

Mold compound 750 may be formed by placing a mold form on substrate 740 and over solar cell 730. The mold form defines an opening over the optically-active area of solar cell 730. Mold piece 770 is placed in the opening such that a bottom surface of mold piece 770 engages with a planar surface of substantially optically-transparent material continuously around a perimeter the optically-active area. Molding compound is injected into the mold form and cured, and the mold form is removed. Optical gel 780 may then be deposited on the planar surface as mentioned above.

FIG. 8 is a cutaway view of optical element 790 placed within mold piece 770 according to some embodiments. Optical element 790 may compress optical gel 780 as shown. According to some embodiments, refractive indexes of optical element 790, optical gel 780, and the substantially optically-transparent material of solar cell 730 are substantially matched. Packaging of a solar cell according to some embodiments is not limited to that shown in FIGS. 7 and 8.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A method comprising:
fabricating a semiconductor base and a semiconductor mesa extending from the semiconductor base, the semiconductor mesa comprising an optically-active semiconductor area and a top surface;
depositing conductive material on the top surface of the mesa; and
depositing substantially optically-transparent material on the conductive material and on the top surface,
wherein a surface of the deposited substantially optically-transparent material above the conductive material and the top surface is substantially planar.

2. A method according to claim 1, further comprising:
depositing an anti-reflective coating on the top surface before depositing the substantially optically-transparent material.

3. A method according to claim 2, wherein the semiconductor mesa comprises a side wall including one or more exposed p-n junctions, and further comprising:
depositing material on the side wall to cover the one or more exposed p-n junctions.

4. A method according to claim 3, wherein depositing the material on the side wall comprises:
depositing the material continuously around a perimeter of the semiconductor mesa.

5. A method according to claim 1, wherein the substantially optically-transparent material comprises an anti-reflective material.

6. A method according to claim 1, further comprising:
depositing a substantially optically-transparent gel on the substantially planar surface,
wherein a refractive index of the substantially optically-transparent gel is substantially similar to a refractive index of the substantially optically-transparent material.

7. A method according to claim 1, further comprising:
placing a mold piece on substantially planar surface; and
forming mold compound around the mold piece and the semiconductor mesa,
wherein the formed mold compound defines an opening above the optically-active semiconductor area.

8. A method according to claim 1, wherein the semiconductor mesa comprises a side wall including one or more exposed p-n junctions, and
wherein depositing the substantially optically-transparent material comprises depositing the substantially optically-transparent material on the side wall to cover the one or more exposed p-n junctions.

9. A method according to claim 8, wherein depositing the substantially optically-transparent material comprises depositing the substantially optically-transparent material continuously around a perimeter of the semiconductor mesa.

10. A device comprising:
a semiconductor mesa extending from a semiconductor base, the semiconductor mesa comprising an optically-active semiconductor area and a top surface;
conductive material disposed on the top surface of the mesa; and
substantially optically-transparent material disposed on the conductive material and on the top surface,
wherein a surface of the substantially optically-transparent material above the conductive material and the top surface is substantially planar.

11. A device according to claim 10, further comprising:
an anti-reflective coating disposed on the top surface of the mesa and under the substantially optically-transparent material.

12. A device according to claim 11, wherein the semiconductor mesa comprises a side wall including one or more exposed p-n junctions, and further comprising
material disposed on the side wall to cover the one or more exposed p-n junctions.

13. A device according to claim 12, wherein the material disposed on the side wall is continuous around a perimeter of the semiconductor mesa.

14. A device according to claim 10, wherein the substantially optically-transparent material comprises an anti-reflective material.

15. A device according to claim 10, further comprising:
a substantially optically-transparent gel disposed on the substantially planar surface.

16. A device according to claim 15, wherein a refractive index of the substantially optically-transparent gel is substantially similar to a refractive index of the substantially optically-transparent material.

17. A device according to claim 10, further comprising:
mold compound formed around the semiconductor mesa,
wherein the formed mold compound defines an opening above the optically-active semiconductor area.

18. A device according to claim 10, wherein the semiconductor mesa comprises a side wall including one or more exposed p-n junctions, and
wherein the substantially optically-transparent material is further disposed on the side wall to cover the one or more exposed p-n junctions.

19. A device according to claim 18, wherein the substantially optically-transparent material is continuous around a perimeter of the semiconductor mesa.
